(19) United States
(12) Patent Application Publication
(10) Pub. No.: US 2019/0372340 A1
(43) Pub. Date: Dec. 5, 2019

(54) POWER SOURCE SURGE PROTECTOR HAVING FAULTY CONSTRUCTION PREVENTION FUNCTION AND FAULTY CONSTRUCTION DETERMINATION METHOD

(71) Applicant: Kyea Kwang LEE, Jung-gu, Daejeon (KR)

(72) Inventor: Kyea Kwang LEE, Jung-gu, Daejeon (KR)

(21) Appl. No.: 16/472,705

(22) PCT Filed: Mar. 27, 2017
(86) PCT No.: PCT/KR2017/003241

§ 371 Date: Jun. 21, 2019

(30) Foreign Application Priority Data
Dec. 30, 2016 (KR) 10-2016-0184386

(51) Int. Cl. H02H 9/04; G01R 19/165

(52) U.S. Cl. CPC H02H 9/042; G01R 19/165

(57) ABSTRACT

The present inventive concept relates to a method of determining installation stability of a power source surge protector and a power source surge protector. The method including: detecting, by a detector at a detection step, a voltage between a phase and a ground, and a voltage between a neutral wire and the ground to transmit the detected voltages to a microcontroller (MCU); and determining, by the MCU at a determination step, whether connection of the phase and the neutral wire is normal by comparing the transmitted voltages with predetermined reference voltages.

### CROSS-REFERENCE TO RELATED APPLICATIONS

This application claims priority to and the benefit of Korean Patent Application No. 10-2016-0184386, filed on Dec. 30, 2016 and PCT Application No PCT/KR2017/003241, filed on Mar. 27, 2017, the entire contents of which are incorporated herein by reference.

### BACKGROUND

The present inventive concept relates to a power source surge protector having a faulty construction prevention function. More particularly, the present inventive concept relates to a power source surge protector and a faulty construction determination method wherein when the power source surge protector is installed in a power system, faulty construction is prevented, and an outlet surge protector, in which a communication surge protector and the power source surge protector are formed into a single body, has a faulty construction prevention function so that installation stability is enhanced.

In general, a power source surge protector adopts KS C IEC61643-11 and KS C IEC61643-12, which are domestic power source surge protector standards.

In a domestic case, a TT system and a TN system are used in combination. According to international standards of the International Electrotechnical Commission (IEC), a TT/TN system typically uses, as shown in FIG. 4, a varistor between L−N and uses a gas discharge tube between N−PE.

As the related art, Korean Patent No. 10-1074663 discloses a two-way surge protective device used in a power supply system having a power breaker, the surge protective device including: a power switch being connected in parallel to a primary side and a secondary side of the power breaker and being capable of breaking electrical connection with the power breaker; a constant voltage element being capable of blocking inflow of lightning surge and removing the same at the primary side of the power breaker and of removing overcurrent at the secondary side of the power breaker.

Also, as the related art, Korean Patent No. 10-0941962 discloses a surge protector capable of determining a ground state, the surge protector including: first and second input terminals; first and second output terminals electrically connected to the first and the second input terminals, respectively; a ground terminal connected to an ground wire; a first surge protector connected in series between the first input terminal and the ground terminal; a second surge protector connected in series between the second input terminal and the ground terminal; a detector measuring a voltage of the first surge protector and the second protector; a controller calculating a ground resistance value of the ground terminal on the basis of the voltage measured by the detector, and determining a ground fault by comparing the ground resistance value with a reference resistance value; and a display displaying whether or not the ground is faulty by an output signal based on the determination of the ground fault by the controller.

However, in installing the conventional surge protection device (SPD), when a phase and a neutral wire are erroneously switched by the operator's mistake, a gas discharge tube is connected between the phase and the ground wire. Thus, when the gas discharge tube operates due to surge, the follow current causes fire, breakdown of a product, or an interruption to the power supply, which may lead to large loss, even to personal injury.

### SUMMARY

Through a power source surge protector having a faulty construction prevention function and a faulty construction determination method, the present inventive concept is intended to propose a power source surge protector with enhanced installation stability and a method of determining installation stability, the surge protector and the method preventing an accident by notifying that faulty construction has occurred when a phase and a neutral wire are erroneously switched by operator's mistake, through a speaker generating a sound and a display, such as an LED, an LCD, a 7-segment display, or the like, which are equipped within the surge protector.

Expanding the description, it is intended to propose an automatic resolution method where in the case of the faulty construction, wiring of the phase and the neutral wire is automatically corrected.

The present inventive concept relates to a faulty construction determination method for a power source surge protector, the method including: detecting, by a detector at a detection step, a voltage between a phase and a ground, and a voltage between a neutral wire and the ground, transmitting the detected voltages to a microcontroller; and determining, by the microcontroller at a determination step, whether connection of the phase and the neutral wire is normal by comparing the transmitted voltages with predetermined reference voltages.

Further, the present inventive concept relates to a power source surge protector with enhanced installation stability, the power source surge protector including: a detector detecting a voltage between a phase and a ground, and a voltage between a neutral wire and the ground to transmit the detected voltages to a microcontroller, the detector being connected between the microcontroller and a phase; an output connected to the microcontroller and generating an alarm; the microcontroller determining whether connection of a phase and a neutral line is normal by comparing the transmitted voltages from the detector with predetermined reference voltages, the microcontroller generating the alarm through the output unit; and a power supply connected to the microcontroller and supplying power to the microcontroller.

Further expanding the description, an automatic faulty-construction prevention function may include a function wherein at the detection step, when detecting that connection of the phase and the neutral wire is erroneous, the connection is corrected automatically through a relay, and the like.

According to the present inventive concept, the power source surge protector with enhanced installation stability and the method of determining installation stability of a power source surge protector can prevent an accident by notifying, when the phase and the neutral wire are erroneously switched by operator's mistake, of information that the phase and the neutral wire are erroneously switched through a speaker generating a sound and a display, such as an LED, an LCD, a 7-segment display, or the like, which are equipped within the surge protector. Further expanding the description, the automatic faulty-construction prevention function has a remarkable effect in preventing an accident by automatically correcting, when detecting that connection of the phase and the neutral wire is erroneous at the detection step, the connection through the relay, and the like.

### BRIEF DESCRIPTION OF THE DRAWINGS

FIG. 1 is a diagram illustrating a configuration of a power source surge protector having a faulty construction prevention function and a faulty construction determination method of the present inventive concept.

FIG. 2 is a diagram illustrating a configuration of a power source surge protector having an automatic faulty-construction prevention function in which a relay of the present inventive concept is installed.

FIGS. 3 and 4 are diagrams illustrating a configuration of the conventional power source surge protector.

### DETAILED DESCRIPTION

The present inventive concept relates to a power source surge protector having a faulty construction prevention function and a faulty construction determination method, the method including: detecting, by a detector at a detection step, a voltage between a phase and a ground, and a voltage between a neutral wire and the ground to transmit the detected voltages to a microcontroller (MCU); and determining, by the MCU at a determination step, whether or not connection of the phase and the neutral wire is normal by comparing the transmitted voltages with predetermined reference voltages.

In case of using AC 220 V, when a measured voltage between the phase and the ground is AC 220 V and a measured voltage between the neutral wire and the ground is from about AC 1 to about 30 V, it is determined that the connection is normal.

Also, the method further includes outputting, at an alarm step, a result of the determination step to a speaker or a display equipped within the surge protector.

Also, at the determination step, when it is determined that the connection of the phase and the neutral wire is abnormal, an automatic correction step in which the microcontroller (MCU) transmits a signal to operate a relay so that the erroneously switched phase and neutral wire are correctly switched to be connected normally in an automatic manner is included

Also, the automatic correction step is performed after the alarm step. However, the automatic correction step is performed without the alarm step.

Also, at the automatic correction step, after correction is completed, a correction-completed alarm is transmitted to a user through a voice message or a text message displayed on a display device 900.

Also, the present inventive concept relates to a power source surge protector having a faulty construction prevention function and a faulty construction determination method, the power source surge protector including: a detector installed inside a surge protector casing and detecting a voltage between a phase and a ground, and a voltage between a neutral wire and the ground to transmit the detected voltages to a microcontroller (MCU); an output unit generating an alarm; the microcontroller determining whether or not connection of the phase and the neutral wire is normal by comparing the transmitted voltages from the detector with predetermined reference voltages, the microcontroller generating the alarm through the output unit; a power supply supplying power, wherein whether or not the connection of the phase and the neutral wire is normal is determined.

Also, the detector has a relay installed, thus, when it is determined that the connection of the phase and the neutral wire is erroneous, the connection of the phase and the neutral wire is automatically corrected internally to be connected normally.

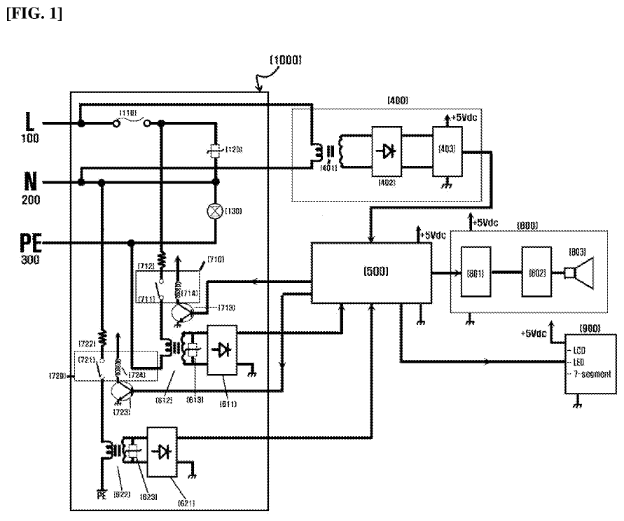

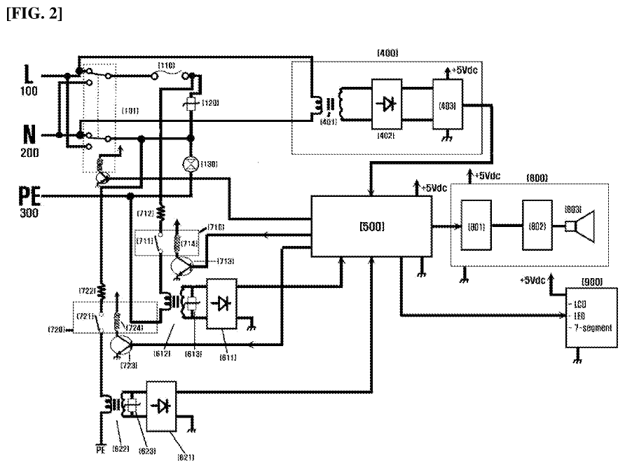

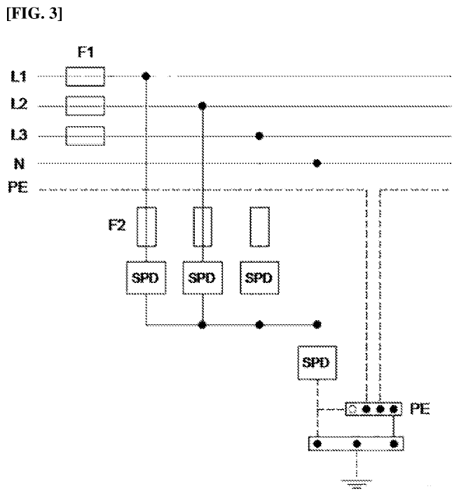

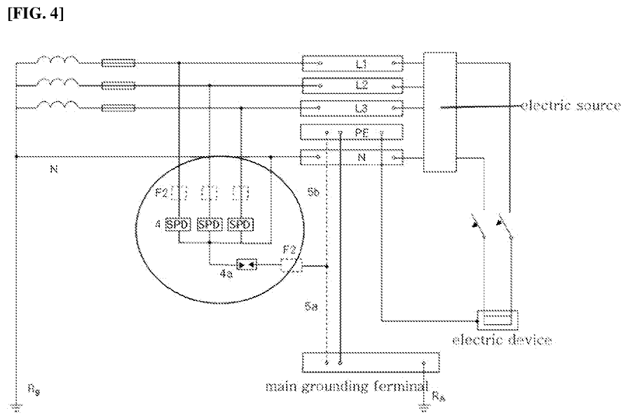

The present inventive concept will be described with reference to the accompanying drawings as follows. FIG. 1 is a diagram illustrating a configuration of a power source surge protector having a faulty construction prevention function and a faulty construction determination method of the present inventive concept. FIG. 2 is a diagram illustrating a configuration of a power source surge protector having an automatic faulty-construction prevention function in which a relay and the like of the present inventive concept are installed. FIGS. 3 and 4 are diagrams illustrating a configuration of the conventional power source surge protector.

In the present inventive concept, the faulty construction determination method for a power source surge protector includes: detecting, by a detector 1000 at a detection step, a voltage between a phase (L) 100 and a ground, and a voltage between a neutral wire (N) 200 and the ground to transmit the detected voltages to a microcontroller (MCU) 500; and determining, by the MCU 500 at a determination step, whether or not connection of the phase (L) 100 and the neutral wire (N) 200 is normal by comparing the transmitted voltages with predetermined reference voltages.

The phase means Line (L) 100, and the neutral wire means Neutral (N) 200.

When using AC 220 V, the predetermined reference voltage between the phase (L) 100 and the ground is AC 220 V and the predetermined reference voltage between the neutral wire (N) 200 and the ground is from about AC 1 V to about 30 V. When the detected voltages are within the above ranges, it is determined that the connection is normal. When the voltage between the phase (L) 100 and the ground is smaller than AC 220V, and the voltage between the neutral wire (N) 200 and the ground is larger than 30 V, it is determined that the connection is abnormal.

In the present inventive concept, the result of the determination step is output to a speaker or a display equipped within the surge protector, thus an alarm is generated so that a worker is alerted whether the connection of the phase (L) 100 and the neutral wire (N) 200 is a normal state or an abnormal state.

When outputting the state of the connection, a recorded file in a voice prompt IC 801 is output to the speaker.

As an example, when the connection is in the normal state, a sound of “connected normally” is output to the speaker or a prompt of “connected normally” is output to the display equipped within the surge protector 10 through an LED, an LCD, or a 7-segment display.

As an example, when the connection is in the abnormal state, a sound of a single-phase surge protector of “-” L and N are erroneously switched, so please turn off the breaker and install again” or “Please check whether the ground terminal is connected” is output to the speaker or a prompt of “L and N are erroneously switched, so please turn off the breaker and install again” or “Please check whether the ground terminal is connected” is output to the display equipped within the surge protector 10 through an LED, an LCD, or a 7-segment display.

As an example, when the connection is in the abnormal state, a sound of a three-phase surge protector of “L1 and N are erroneously switched, so please turn off the breaker and install again,” ““L2 and N are erroneously switched, so please turn off the breaker and install again,” “L3 and N are erroneously switched, so please turn off the breaker and install again, or “Please check whether the ground terminal is connected” and so on is output to the display equipped within the surge protector 10 through an LED, an LCD, or a 7-segment display

Further, when the abnormal connection state is determined and the connection state is changed to the normal connection state through the relay, the corresponding content is displayed on a connection terminal of the phase (L) 100 and the neutral wire (N) 200.

In the meantime, in the present inventive concept, at the determination step, when it is determined that the connection between the phase (L) 100 and the neutral wire (N) 200 is abnormal, the microcontroller (MCU) 500 transmits a signal to operate the relay 710 so that the erroneously switched phase (L) 100 and neutral wire (N) 200 are correctly switched for automatic correction to be connected normally.

In this case, the automatic correction step may be operated after the alarm step.

Further, in the automatic correction step, after correction is completed, the correction-completed fact is noticed as a voice message such as “correction is completed” or “installed normally”, or a prompt such as “correction is completed” or “installed normally” through a display device 900.

The circuit of the surge protector 10 of the present inventive concept will be described as follows.

The circuit of the surge protector 10 including a detector 1000; a power supply 400; the microcontroller (MCU) 500; and an output unit 800 and 900.

In the detector, a varistor 120 is connected between the phase (L) 100 and the neutral wire (N) 200, and a gas discharge tube 130 is connected between the neutral wire (N) 200 and the ground (PE) 300. Inlet terminals of the phase (L) 100 and the neutral wire (N) 200 are connected to a transformer 401 in the power supply 400 in series.

A fuse 110, for example, a thermal fuse, is connected between an end of the phase line (L) 100 and the varistor 120. Further, the phase line (L) 200 disposed between the thermal fuse 110 and the varistor 120 is grounded via a resistor 712, a switch 711 in a relay 710 and a transformer 612 which are sequentially connected in series. A transistor 713 for on/off control of the relay 710 is connected to a microcontroller 500. The transformer 612 is connected to a bridge diode 611 in series and a varistor 613 is connected in parallel with the bridge diode 611 between the bridge diode 611 and the transformer 612 for protection against a transient voltage of the transformer 612. An output terminal of the bridge diode 611 is connected to the microcontroller 500 through a detector 1000 which detect voltage, and the other output terminal of the bridge diode is grounded.

The neutral wire (N) 100 is grounded via a resistor 722, a switch 721 in a relay 720 and a transformer 622 which are sequentially connected in series. Further, a transistor 723 for on/off control of the relay 720 is connected to a microcontroller 500. The transformer 622 is connected to a bridge diode 621 in series, and a varistor 623 is connected in parallel with the bridge diode 621 between the bridge diode 621 and the transformer 622 for protection against a transient voltage of the transformer. An output terminal of the bridge diode is connected to the microcontroller unit in series through the detector 1000, and the other output terminal of the bridge diode is grounded.

Regarding the power supply 400, two output terminals of a constant voltage supply 403 are connected to a bridge diode 402 in series through two lines, and the bridge diode 402 is connected to the transformer 401 in series through two lines. The transformer 401 is connected to inlet terminals of the phase line (L) 100 and the neutral wire (N) 200 of the detector in series. The other output terminal of the constant voltage supply is connected to the input terminal of the microcontroller 500 in series.

A voice prompt 801 that is connected to the output terminal of the microcontroller 500 in series is connected to an amplifier 802 in series, and the amplifier is connected to a speaker 803 in series. Alternatively, the display 900 having a LED, an LCD, or a 7-segment display is connected to the microcontroller 500 in series for display.

One of the input terminals of the microcontroller 500 is connected to the output terminal of the constant voltage supply 403 of the power supply 400 in series. One of the output terminals of the microcontroller 500 is connected to the voice prompt 801 of the output unit in series, and one of the output terminals of the microcontroller 500 is connected to the display 900 of the output unit, which has an LED, an LCD, or a 7-segment display, in series for display.

One of the output terminals of the microcontroller 500 is connected to the transistor 723 to operate the relay 720 disposed between the neutral wire (N) 200 and the ground wire PE. One of the input terminals of the microcontroller is connected in series to the output terminal of the bridge diode 621 that is connected in series to the transformer 622 which is connected in series between the neutral wire (N) 200 and the ground PE.

One of the output terminals of the microcontroller 500 is connected to the transistor 713 to operate the relay 710 disposed between the phase (L) 100 and the ground wire PE. One of the input terminals of the microcontroller 500 is connected in series to the detector 1000 that is connected to the output terminal of the bridge diode 611 which is connected in series to the transformer 612 connected in series between the phase (L) 100 and the ground PE.

The voice output 800 includes the voice prompt 801 determining a voice according to a signal of the microcontroller 500; the signal amplifier (Audio-Amp) 802 amplifying a signal of the voice determined by the voice prompt 801; and the speaker 803 outputting the voice amplified through the signal amplifier 802 into a sound.

The voice prompt 801 may include an IC in which a voice file is pre-stored.

The microcontroller 500 may determine, in consideration of the measured voltage by the detector 1000, whether the circuit is connected normally. According to the connection state, the output unit 800 and/or 900 is controlled to output the state of the connection through the voice output 800 by transmitting the voice file stored in the integrated circuit (IC) of the voice prompt 801 to the speaker 803 through the signal amplifier (Audio Amp) 802 or through the display 900.

In case of using AC 220 V, when a measured voltage between the phase (L) 100 and the ground (PE) 300 is AC 220 V, and a measured voltage between the neutral wire (N) 200 and the ground (PE) 300 is from about AC 1 to about 30 V, it is determined that the connection is normal.

The display 900 may use a light emitting diode (LED), a liquid crystal display (LCD), a 7-segment display (seven-segment display), or the like.

The microcontroller 500 determines states of connection into the normal connection state and the abnormal connection state, and output information according to the determined state.

When the state is determined to be the normal connection state, signals are transmitted to the display 900 and the voice prompt 801, respectively. The display 900 performs output so that the normal state is recognized. The voice prompt 801 selects a voice file set to be output in the case of the normal connection and outputs the same to the speaker through the signal amplifier (Audio-Amp) 802.

As an example, after the microcontroller 500 determines the normal connection state, signals are transmitted to a blue light emitting diode and the voice prompt 801, respectively. The blue light emitting diode receiving the signal outputs blue light, and the voice prompt 801 receiving the signal executes the voice file set to be output in the case of the normal connection state, among voice files. When the voice file is executed, a signal is transmitted to the signal amplifier (Audio-Amp), the signal amplifier (Audio-Amp) amplifies the voice to output voice “connected normally” through the speaker.

When the microcontroller 500 determines the state to be the abnormal connection state, signals are transmitted to the display 900 and the voice prompt 801, respectively. The display 900 performs output so that the abnormal state is recognized. The voice prompt 801 selects the voice file set to be output in the case of the abnormal connection state, and outputs the voice file set to be output in the case of the abnormal connection to the speaker 803 through the signal amplifier (Audio-Amp) 802.

As an example, after the microcontroller 500 determines the abnormal connection state, signals are transmitted to a red light emitting diode and the voice prompt 801 according to the problem situation, respectively.

The red light emitting diode receiving the signal outputs red light, and the voice prompt receiving the signal executes the voice file set to be output in the case of the abnormal connection state, among voice files. According to kinds of problems, the corresponding voice file is selected, the voice file is executed, and a signal is transmitted to the signal amplifier (Audio-Amp).

The signal amplifier (Audio-Amp) 802 amplifies the voice and outputs the resulting voice through the speaker. The voice of the voice file selected according to the kinds of problems is output. Here, when the surge protector being used is a single-phase surge protector, the problem occurs when the phase (L) 100 and the neutral wire (N) 200 are not connected correctly and when the ground (PE) 300 is not connected. When the surge protector being used is a three-phase surge protector, the problem occurs when one among phase 1 (L1), phase 2 (L2), and phase 3 (L3) and the neutral wire are not connected correctly and when the ground (PE) 300 is not connected.

In particular, when using the single-phase surge protector, the voice set to be output is one among “the phase and the neutral wire are erroneously switched, so please turn off the breaker and install again” and “please check whether the ground terminal is connected”. When using the three-phase surge protector, the voice set to be output is one among “phase 1 and the neutral wire are erroneously switched, so please turn off the breaker and install again”, “phase 2 and the neutral wire are erroneously switched, so please turn off the breaker and install again”, “phase 3 and the neutral wire are erroneously switched, so please turn off the breaker and install again”, and “please check whether the ground terminal is connected”.

In the meantime, as another example in the present inventive concept, a relay and the like are installed, which enable the incorrectly connected phase (L) 100 and neutral wire (N) 200 to be connected normally in an automatic manner. The relay and the like perform correction in such a manner that the incorrectly connected phase and neutral wire are switched to be connected normally in an automatic manner. When receiving a signal from the microcontroller 500, a phase switch of the relay operates. Then, the initial phase line is turned off, and instead, the line branched from the phase line becomes a neutral wire. When a switch of the neutral wire operates, the initial neutral wire is turned off; the line branched from the neutral wire becomes a phase line. Consequently, the phase and the neutral wire are switched.

The operation sequence of the present inventive concept will be described in detail as follows. Usually, a phase wire relay 710 and a neutral wire relay 720 are all open so that no current flows between the phase (L) 100 and the ground (PE) 300 and between the neutral wire (N) 200 and the ground (PE) 300. Therefore, when main power enters from the power supply 400, the microcontroller 500 operates and the relays 710 and 720 of the phase and the neutral wire operate, and very weak current flows between the phase (L) 100 and the ground (PE) 300 and between the neutral wire (N) 200 and the ground (PE) 300. Then, the voltage between the phase (L) 100 and the ground (PE) 300, and the voltage between the neutral wire (N) 200 and the ground (PE) 300 are measured by the transformers 612 and 622.

The measured voltages are transmitted to the microcontroller 500, and the microcontroller 500 determines whether or not the connection is normal. When the voltage between the phase and the ground, and the voltage between the neutral wire and the ground are not in a predetermined range, it is determined that the phase and the neutral wire are not connected properly, so an alarm signal is output.

Furthermore, the voltage between the phase and the ground, and the voltage between the neutral wire and the ground are detected through the transformers for detecting the voltages. The relay and the like may alter the connection of the phase and the neutral wire to be the normal connection state automatically. After being connected normally, the microcontroller turns off the relay so that no leakage current is present.

1. A faulty construction determination method for a power source surge protector, the method comprising:
detecting, by a detector at a detection step, a voltage between a phase and a ground, and a voltage between a neutral wire and the ground,
transmitting the detected voltages to a microcontroller; and
determining, by the microcontroller at a determination step, whether connection of the phase and the neutral wire is normal by comparing the transmitted voltages with predetermined reference voltages.

2. The method of claim 1, wherein the predetermined reference voltages between the phase and the ground is, and the predetermined preset reference voltages between the neutral wire and the ground is from about AC 1 to about 30 V when using AC 220 V.

3. The method of claim 1, further comprising:
outputting, at an alarm step, a result of the determination step to a speaker or a display equipped within the surge protector.

4. The method of claim 3, further comprising, an automatic correction step after the determination step, during the automatic correction step, the microcontroller transmits a signal to operate a relay to correct a connection state of the phase and the neutral wire, and the relay corrects the connection state of the phase and the neutral wire according to the signal.

5. The method of claim 4, further comprising an alarm step which notifies the connection state of the phase and the neutral wire before the automatic correction step.

6. The method of claim 5, further comprising an alarm step which notifies that the connection of the phase and the neutral wire is in a normal state after the automatic correction is completed.

7. The power source surge protector of claim 1,
when both the voltage between the phase and the ground, and the voltage between the neutral wire and the ground are not in the predetermined reference voltages, the microcontroller decides that the ground wire is disconnected.

8. A power source surge protector having a faulty construction prevention function, the power source surge protector comprising:
a detector detecting a voltage between a phase and a ground, and a voltage between a neutral wire and the ground to transmit the detected voltages to a microcontroller, the detector being connected between the microcontroller and a phase;
an output connected to the microcontroller and generating an alarm;
the microcontroller determining whether connection of a phase and a neutral line is normal by comparing the transmitted voltages from the detector with predetermined reference voltages, the microcontroller generating the alarm through the output unit; and
a power supply connected to the microcontroller and supplying power to the microcontroller.

9. The power source surge protector of claim 7, wherein the detector has a relay connected to the microcontroller, the phase and a ground when it is determined that the connection of the phase and the neutral wire is abnormal, the erroneously switched phase and neutral wire are correctly switched to be connected normally in an automatic manner.
